(19) United States
(12) Patent Application Publication
(10) Pub. No.: US 2020/0025638 A1
(43) Pub. Date: Jan. 23, 2020

(54) DIFFERENTIAL PRESSURE SENSOR CHIP, DIFFERENTIAL PRESSURE TRANSMITTER, AND METHOD FOR MANUFACTURING DIFFERENTIAL PRESSURE SENSOR CHIP

(71) Applicant: AZBIL CORPORATION, Chiyoda-ku (JP)

(72) Inventors: Ayumi TSUSHIMA, Chiyoda-ku (JP); Yoshiyuki ISHIKURA, Chiyoda-ku (JP); Tomohisa TOKUDA, Chiyoda-ku (JP)

(73) Assignee: AZBIL CORPORATION, Chiyoda-ku (JP)

(21) Appl. No.: 16/495,626

(22) PCT Filed: Jan. 16, 2018
(86) PCT No.: PCT/JP2018/000933

§ 371 Date: Sep. 19, 2019

(30) Foreign Application Priority Data
Mar. 22, 2017 (JP) 2017-056190

(51) Int. Cl. G01L 13/06; H01L 41/113; H01L 41/22; G01L 9/00

(52) U.S. Cl. CPC G01L 13/06; G01L 9/0052; H01L 41/22; H01L 41/1132

(57) ABSTRACT

A differential pressure sensor chip (2) includes: first and second pressure introduction holes (21_1 and 21_2); first and second diaphragms (23_1 and 23_2) formed to cover the first and second pressure introduction holes; first and second depressions (24_1 and 24_2) each in a form of a depression respectively provided to face the first and second pressure introduction holes with the first and second diaphragms interposed therebetween; a first communication channel (25) that makes a chamber between the first depression and the first diaphragm and a chamber between the second depression and the second diaphragm communicate to each other; a pressure-transmission-material introduction passage (26) an end of which is an opening and another end of which is joined to the first communication channel; a pressure transmission material (27) that fills the first communication channel, the two chambers, and the pressure-transmission-material introduction passage; and a sealing member (7) formed of a metal formed to seal a depression on a metal layer (9) formed on a surface of the opening of the pressure-transmission-material introduction passage.

### TECHNICAL FIELD

The present invention relates to a differential pressure sensor chip that detects a differential between two or more fluid pressures, a differential pressure transmitter using the differential pressure sensor chip, and a method for manufacturing the differential pressure sensor chip.

### BACKGROUND ART

In the related art, as a device for measuring a differential between two or more fluid pressures in various process systems, a differential pressure transmitter has been known.

As a form of the differential pressure transmitter, there is a device including a first diaphragm and a second diaphragm that are formed of a semiconductor film, in which a differential between the pressures applied to the diaphragms is converted into a change in the resistance of a piezoresistor and an electric signal based on the change in resistance is output as a pressure measurement result.

As the differential pressure transmitter, for example, a parallel-diaphragm-type differential pressure transmitter using a sensor chip having the following structure has been known (e.g., see PTLs 1 and 2). A first diaphragm and a second diaphragm formed of a semiconductor film in which a piezoresistor is formed are formed in parallel in a plane direction in a semiconductor chip, and two chambers formed immediately above the diaphragms are spatially joined to each other via a communication channel.

In the parallel-diaphragm-type differential pressure transmitter, typically, in order to transmit a pressure applied to one of the diaphragms to the other of the diaphragms, the two chambers and the communication channel are filled with a pressure transmission material (oil).

As an oil-enclosing method of the related art, the following method has been known (e.g., see PTL 3). An oil filling pipe, which is a metal component, is adhered to the sensor chip, and the oil is enclosed in the sensor chip through the oil filling pipe. Subsequently, an end of the oil filling pipe is crushed and sealed by welding or soldering.

### CITATION LIST

### Patent Literature

PTL 1: Japanese Unexamined Patent Application Publication No. 53-20956

PTL 2: Japanese Unexamined Patent Application Publication No. 5-22949

PTL 3: Japanese Unexamined Patent Application Publication No. 2003-194649

### SUMMARY OF INVENTION

### Technical Problem

By the way, the oil enclosed in the sensor chip of the differential pressure transmitter expands or contracts depending on a change in an ambient environment of the sensor chip. For example, if the temperature changes in a range from −40° C. to 110° C., even if no pressure is applied from a fluid that is a detection target, the oil expands or contracts, which results in deformation of the diaphragms in the sensor chip. In a state of the deformation of the diaphragms as a result of expansion or contraction of the oil in the above manner, if a pressure is applied to the diaphragms from the fluid that is a detection target, the pressure detection sensitivity of the differential pressure transmitter may be decreased, or the diaphragms may be broken owing to generation of excessive stress on the diaphragms.

Therefore, in order to reduce the influence of the expansion or contraction of the oil introduced into the sensor chip, which is caused by heat, it is desirable to reduce the amount of the oil enclosed in the sensor chip as much as possible.

However, the sensor chip in which the oil is introduced by using the method disclosed in PTL 3 has a structure in which an oil introducing hole of the sensor chip is sealed by using the oil filling pipe (metal component) formed of metal. Thus, not only the two chambers and the communication channel but also the oil filling pipe is filled with the oil. Accordingly, the total amount of the oil in the sensor is large, and the pressure detection sensitivity may be decreased, or the diaphragms may be broken as described above.

In addition, in the method disclosed in PTL 3, the amount of the oil in the sensor chip depends on a design tolerance of the oil filling pipe or an adhesive area controllability of an adhesive for fixing the oil filling pipe to the sensor chip. Therefore, it is not easy to control the amount of the oil.

Furthermore, in a case of using the oil filling pipe, the front end of the oil filling pipe protrudes from the surface of the chip when the oil filling pipe is fixed to the chip. Thus, the oil filling pipe becomes a physical obstacle in a wafer process, a packaging process, and the like, and restrictions are generated in manufacturing steps of the differential pressure transmitter. For example, the order of the manufacturing steps is restricted as described below. Individual sensor chips are cut out from a wafer, and a bonding step, a wire bonding step, and the like are performed, followed by adhering of the oil filling pipe to each of the sensor chips and enclosing of the oil. This is disadvantageous in reducing the manufacturing cost of the differential pressure transmitter.

The present invention has been made in view of the above problem. An object of the present invention is to realize, at a lower cost, a differential pressure transmitter including a parallel-diaphragm-type differential pressure sensor chip in which a necessary and sufficient amount of a pressure transmission material is enclosed.

### Solution to Problem

A differential pressure sensor chip according to the present invention detects a differential pressure of a fluid that is a measurement target. The differential pressure sensor chip includes: a first base portion (20) including a first main surface (20a), a second main surface (20b) opposite to the first main surface, and a first pressure introduction hole (21_1) and a second pressure introduction hole (21_2) that are each open on the first main surface and the second main surface; a semiconductor film (23) formed on the second main surface of the first base portion; and a second base portion (22) including a third main surface and a fourth main surface (22b) opposite to the third main surface (22a), the third main surface being bonded to the semiconductor film. The semiconductor film includes a first diaphragm (23_1) formed to cover an end of the first pressure introduction hole, a second diaphragm (23_2) formed to cover an end of the second pressure introduction hole, a first strain gauge (230_1) provided for the first diaphragm and configured to detect a pressure of the fluid that is the measurement target, and a second strain gauge (230_2) provided for the second diaphragm and configured to detect a pressure of the fluid that is the measurement target. The second base portion includes a first depression (24_1) formed at a position on the third surface facing the first pressure introduction hole with the first diaphragm interposed therebetween and forming a first chamber (28_1) together with the first diaphragm, a second depression (24_2) formed at a position on the third surface facing the second pressure introduction hole with the second diaphragm interposed therebetween and forming a second chamber (28_2) together with the second diaphragm, a first communication channel (25) that makes the first chamber and the second chamber communicate to each other, a pressure-transmission-material introduction passage (26) including a third depression (260) formed on the fourth main surface and a second communication channel (261) that makes the third depression and the first communication channel communicate to each other, a metal layer (9) formed on a surface of the third depression, a pressure transmission material (27) that fills the first chamber, the second chamber, the first communication channel, and the pressure-transmission-material introduction passage, and a sealing member (7) that seals the third depression on the metal layer and that is formed of a metal.

In the above differential pressure sensor chip, the third depression may be a hemispherical hole formed on the fourth main surface.

In the above differential pressure sensor chip, the sealing member may be formed of a metal material that is melted within the third depression.

In the above differential pressure sensor chip, the metal material may include gold.

A differential pressure transmitter (100) according to the present invention includes: the differential pressure sensor chip (2) according to the present invention; a base (1) including a fifth main surface, a sixth main surface (1b) opposite to the fifth main surface (1a), and a first fluid pressure introduction hole (11_1) and a second fluid pressure introduction hole (11_2) that are each open on the fifth main surface and the sixth main surface; a third diaphragm (10_1) formed on the fifth main surface of the base to cover an end of the first fluid pressure introduction hole; a fourth diaphragm (10_2) formed on the fifth main surface of the base to cover an end of the second fluid pressure introduction hole; and a supporting substrate (3) including a seventh main surface (3a), an eighth main surface (3b) opposite to the seventh main surface, and a first through hole (30_1) and a second through hole (30_2) that are each open on the seventh main surface and the eighth main surface, the seventh main surface being fixed onto the base, the eighth main surface being bonded to the first main surface of the first base portion, the supporting substrate supporting the differential pressure sensor chip. The first fluid pressure introduction hole and the first through hole communicate to each other. The second fluid pressure introduction hole and the second through hole communicate to each other.

### Advantageous Effects of Invention

According to the present invention, it is possible to realize, at a lower cost, a differential pressure transmitter including a parallel-diaphragm-type differential pressure sensor chip in which a necessary and sufficient amount of a pressure transmission material is enclosed.

### BRIEF DESCRIPTION OF DRAWINGS

FIG. 1 illustrates a configuration of a differential pressure transmitter including a differential pressure sensor chip according to an embodiment of the present invention.

FIG. 2A is a sectional view illustrating a schematic structure of the periphery of an oil introduction passage of the differential pressure sensor chip.

FIG. 2B is a top view illustrating a schematic structure of the periphery of the oil introduction passage of the differential pressure sensor chip.

FIG. 2C is a perspective view illustrating a schematic structure of the periphery of the oil introduction passage of the differential pressure sensor chip.

FIG. 3A illustrates a chip fabrication process in a method for manufacturing the differential pressure sensor chip.

FIG. 3B illustrates the chip fabrication process in the method for manufacturing the differential pressure sensor chip.

FIG. 3C illustrates the chip fabrication process in the method for manufacturing the differential pressure sensor chip.

FIG. 3D illustrates the chip fabrication process in the method for manufacturing the differential pressure sensor chip.

FIG. 3E illustrates the chip fabrication process in the method for manufacturing the differential pressure sensor chip.

FIG. 3F illustrates the chip fabrication process in the method for manufacturing the differential pressure sensor chip.

FIG. 3G illustrates the chip fabrication process in the method for manufacturing the differential pressure sensor chip.

FIG. 3H illustrates the chip fabrication process in the method for manufacturing the differential pressure sensor chip.

FIG. 4A illustrates an oil enclosing process in the method for manufacturing the differential pressure sensor chip.

FIG. 4B illustrates the oil enclosing process in the method for manufacturing the differential pressure sensor chip.

FIG. 4C illustrates the oil enclosing process in the method for manufacturing the differential pressure sensor chip.

FIG. 4D illustrates the oil enclosing process in the method for manufacturing the differential pressure sensor chip.

FIG. 5A is a sectional view illustrating a schematic structure of another first example of the oil introduction passage.

FIG. 5B is a perspective view illustrating the schematic structure of the other first example of the oil introduction passage.

FIG. 6A is a sectional view illustrating a schematic structure of another second example of the oil introduction passage.

FIG. 6B is a perspective view illustrating the schematic structure of the other second example of the oil introduction passage.

FIG. 7 illustrates another structure of a pressure introduction passage of the differential pressure sensor chip.

### DESCRIPTION OF EMBODIMENTS

Now, an embodiment of the present invention will be described with reference to the drawings. Note that in the following description, the same reference numerals denote common components in each embodiment, and a repeated description thereof will be omitted.

### Embodiment

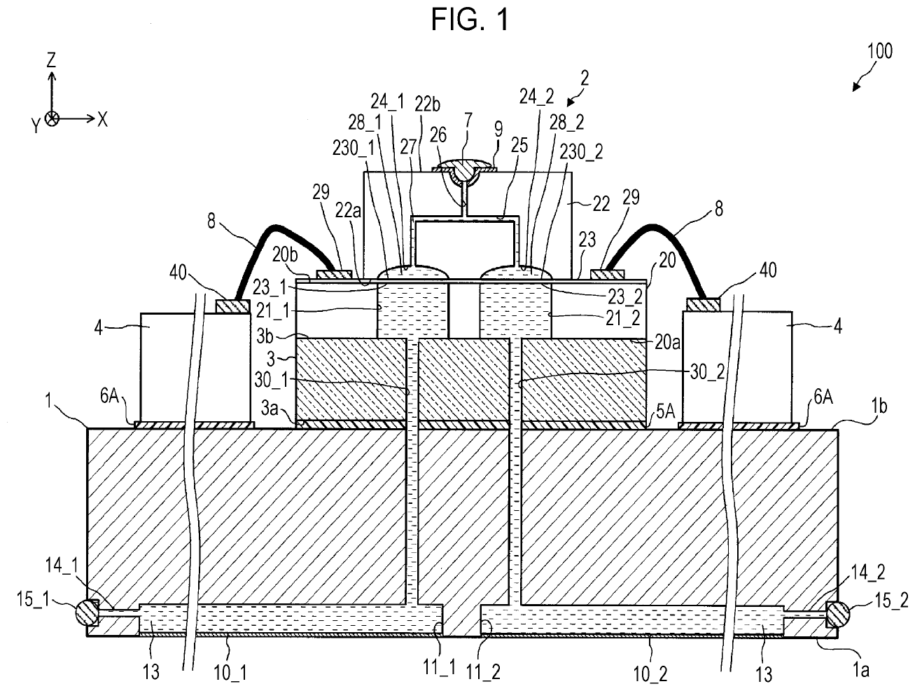

FIG. 1 illustrates a configuration of a differential pressure transmitter including a differential pressure sensor chip according to the embodiment of the present invention. The same drawing schematically illustrates a sectional shape of a differential pressure transmitter 100 according to this embodiment.

In the differential pressure transmitter 100 illustrated in FIG. 1, a first diaphragm and a second diaphragm formed of a semiconductor film in which a pressure-sensitive element is formed are formed in parallel in a plane direction. In addition, the differential pressure transmitter 100 is a parallel-diaphragm-type differential pressure transmitter using a sensor chip having a structure in which two chambers formed immediately above the diaphragms are spatially joined to each other via a communication channel.

As main functional units for detecting a differential pressure of a fluid that is a measurement target, the differential pressure transmitter 100 includes a differential pressure sensor chip 2, a supporting substrate 3, a diaphragm base 1, and a relay substrate 4. Now, the above functional units will be described in detail.

Note that this embodiment will describe the main functional units for detecting a differential pressure of a fluid in detail among all the functional units of the differential pressure transmitter 100, and a detailed description and drawings of the other functional units will be omitted. For example, a detailed description and drawings will be omitted for functional units of a signal processing circuit that performs various kinds of signal processing based on an electric signal corresponding to the pressure detected by the differential pressure sensor chip 2, of a display apparatus that outputs various kinds of information based on a result of signal processing by the signal processing circuit, and the like.

(1) Differential Pressure Sensor Chip 2

The differential pressure sensor chip 2 is a semiconductor chip that detects the differential pressure of the fluid that is the measurement target.

The differential pressure sensor chip 2 has a structure in which, for example, a first base portion 20 and a second base portion 22 are bonded with a semiconductor film 23 having a diaphragm function interposed therebetween.

The first base portion 20 is formed of silicon, for example. In the first base portion 20, through the diaphragm base 1 and the supporting substrate 3, which will be described later, a pressure introduction hole 21_1 for introducing a pressure of the fluid that is the measurement target and a pressure introduction hole 21_2 for introducing another pressure of the fluid that is the measurement target are formed.

The pressure introduction holes 21_1 and 21_2 are through holes formed through a main surface 20a of the first base portion 20 and a main surface 20b that is opposite to the main surface 20a. The pressure introduction holes 21_1 and 21_2 are formed to be separated from each other in the plane direction on the main surfaces 20a and 20b of the first base portion 20.

The semiconductor film 23 is formed on the main surface 20b of the first base portion 20 to cover at least the pressure introduction holes 21_1 and 21_2. The semiconductor film 23 is formed of silicon, for example.

In the semiconductor film 23, a region covering the pressure introduction hole 21_1 and a region covering the pressure introduction hole 21_2 each function as a diaphragm. Hereinafter, the region of the semiconductor film 23 covering the pressure introduction hole 21_1 will be referred to as a diaphragm 23_1, and the region of the semiconductor film 23 covering the pressure introduction hole 21_2 will be referred to as a diaphragm 23_2.

The semiconductor film 23 includes a pressure-receiving surface and a surface opposite to the pressure-receiving surface. On the pressure-receiving surface, a pressure based on the fluid that is the measurement target is received from the pressure introduction holes 21_1 and 21_2. In the semiconductor film 23 on the surface opposite to the pressure-receiving surface, strain gauges 230_1 and 230_2 are formed as a plurality of pressure-sensitive elements for detecting the pressures applied to the diaphragms 23_1 and 23_2.

The strain gauges 230_1 and 230_2 include a plurality of piezoresistors, for example. The plurality of piezoresistors form a bridge circuit. When a stress is generated in the diaphragms 23_1 and 23_2 in a state where a fixed current flows, the bridge circuit serves as a differential pressure detecting unit that outputs, as a change in voltage, a change in the resistance of each of the piezoresistors due to the stress.

The nodes in the bridge circuit are respectively connected to, through a wiring pattern formed on the surface opposite to the pressure-receiving surface of the semiconductor film 23, a plurality of electrode pads 29 that are formed on the surface opposite to the pressure-receiving surface as well.

The second base portion 22 is formed of silicon, for example. The second base portion 22 is fixed onto the first base portion 20 with the semiconductor film 23 interposed therebetween. Specifically, a main surface 22a of the second base portion 22 is bonded to a surface of the semiconductor film 23 that is not bonded to the first base portion 20.

In the second base portion 22, depressions 24_1 and 24_2, a first communication channel 25, and a pressure-transmission-material introduction passage 26 are formed.

The depressions 24_1 and 24_2 are functional units that restrict deformation of the diaphragms 23_1 and 23_2 in one direction in the following manner. If a pressure is applied to the diaphragms 23_1 and 23_2 from the pressure introduction holes 21_1 and 21_2 of the first base portion 20 to flex the diaphragms 23_1 and 23_2, the diaphragms 23_1 and 23_2 reach the depressions 24_1 and 24_2. This can prevent the diaphragms 23_1 and 23_2 from being broken as a result of an excessive pressure being applied to the diaphragms 23_1 and 23_2. Hereinafter, the depressions 24_1 and 24_2 will also be referred to as “stopper portions 24_1 and 24_2”.

Specifically, the stopper portions 24_1 and 24_2 are depressions (recesses) formed on a surface of the second base portion 22 to be bonded to the semiconductor film 23, in a direction vertical to the bonding surface (Z-direction). The stopper portion 24_1 is disposed to face the pressure introduction hole 21_1 with the diaphragm 23_1 interposed therebetween. The stopper portion 24_2 is disposed to face the pressure introduction hole 21_2 with the diaphragm 23_2 interposed therebetween. The depressions forming the stopper portions 24_1 and 24_2 have a curved shape (e.g., aspherical surface) in accordance with the displacement of the diaphragms 23_1 and 23_2.

A space is provided between the stopper portion 24_1 and the diaphragm 23_1 and between the stopper portion 24_2 and the diaphragm 23_2. Hereinafter, the space provided between the stopper portion 24_1 and the diaphragm 23_1 will be referred to as a chamber 28_1. In addition, the space provided between the stopper portion 24_2 and the diaphragm 23_2 will be referred to as a chamber 28_2.

The chamber 28_1 and the chamber 28_2 communicate to each other via the first communication channel 25. In other words, the chamber 28_1 and the chamber 28_2 are spatially joined to each other via the first communication channel 25.

For example, as illustrated in FIG. 1, the configuration is formed by two holes that extend in the Z-axis direction from the surface of the stopper portions 24_1 and 24_2 and a hole that extends in a direction vertical to the Z-axis and makes the two holes communicate to each other.

The first communication channel 25 serves as a pressure communication channel for transmitting a pressure applied to one of the diaphragms 23_1 and 23_2 to the other of the diaphragms 23_1 and 23_2. Hereinafter, the first communication channel 25 will also be referred to as “pressure communication channel 25”.

On a main surface 22b of the second base portion 22 opposite to the main surface 22a, a pressure-transmission-material introduction passage 26 that communicates to the pressure communication channel 25 is formed. Furthermore, a metal layer 9 is formed in the opening of the pressure-transmission-material introduction passage 26.

The pressure-transmission-material introduction passage 26, the pressure communication channel 25, and the chambers 28_1 and 28_2 are filled with a pressure transmission material 27. The pressure transmission material 27 is a material for transmitting a pressure applied to one of the diaphragms 23_1 and 23_2 to the other of the diaphragms 23_1 and 23_2 through the pressure communication channel 25.

Examples of the pressure transmission material 27 include silicone oil, fluorine oil, and the like.

In this embodiment, as an example, the pressure transmission material 27 is a liquid (e.g., silicone oil), and the pressure transmission material 27 will also be referred to as “oil 27”, and the pressure-transmission-material introduction passage 26 will also be referred to as “oil introduction passage 26”.

A sealing member 7 is a functional unit that seals an end of the oil introduction passage 26 after the oil 27 has been introduced to the chambers 28_1 and 28_2 and the pressure communication channel 25 through the oil introduction passage 26. Hereinafter, the oil introduction passage 26, the metal layer 9, and the sealing member 7 will be described in detail.

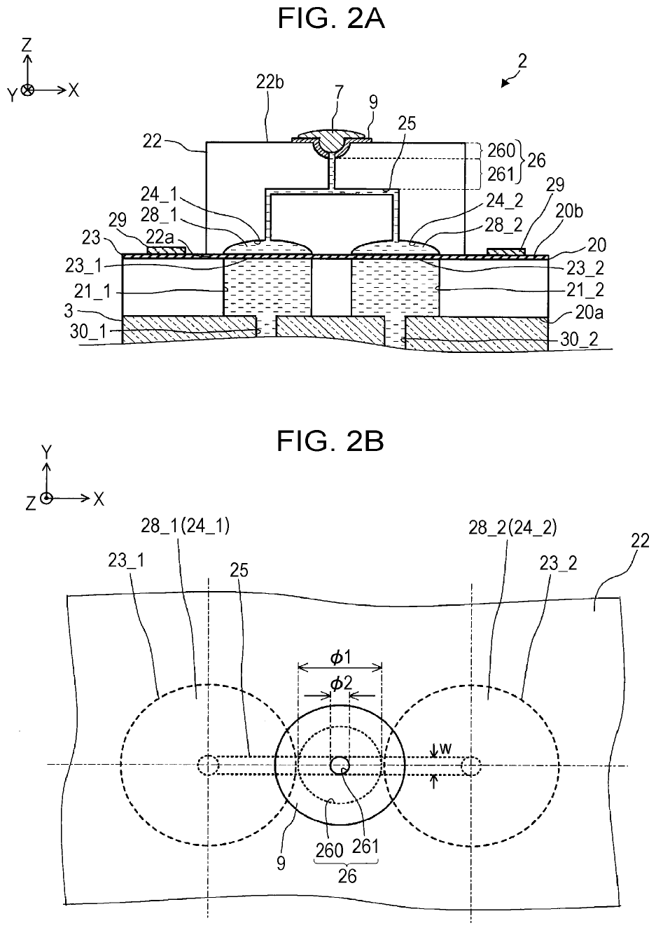

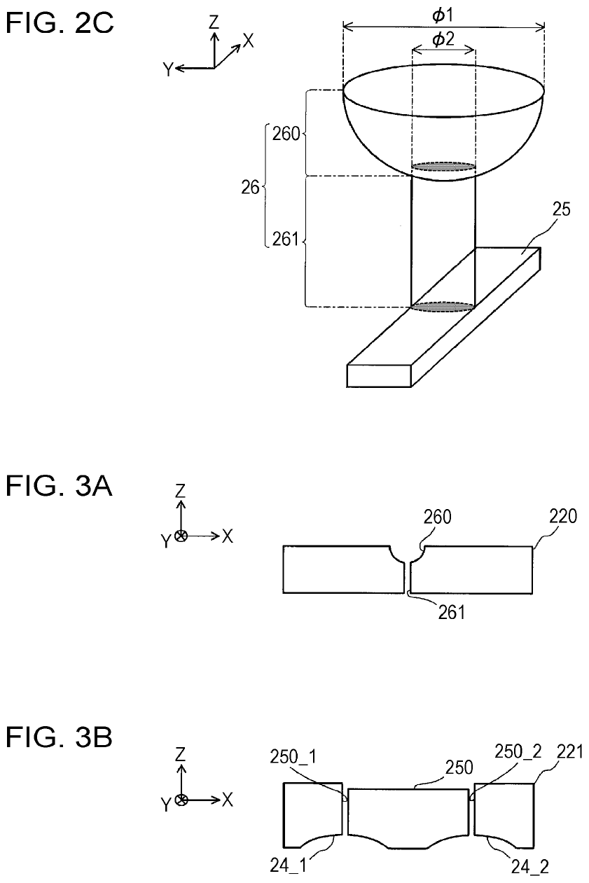

FIG. 2A illustrates a sectional view of the periphery of the oil introduction passage 26 of the differential pressure sensor chip 2. FIG. 2B illustrates a top view of the periphery of the oil introduction passage 26 of the differential pressure sensor chip 2. FIG. 2C illustrates a perspective view of the periphery of the oil introduction passage 26 of the differential pressure sensor chip 2.

Note that the metal layer 9 and the sealing member 7 are omitted from illustration in FIG. 2B. In addition, FIG. 2C schematically illustrates a part of the passage through which the oil 27 flows.

As illustrated in FIGS. 2A to 2C, the oil introduction passage 26 includes a depression 260 formed on the main surface 22b of the second base portion 22 and a communication channel 261 that makes the depression 260 and the pressure communication channel 25 communicate to each other.

Specifically, the depression 260 is a hemispherical hole formed on the main surface 22b of the second base portion 22 and is formed to be substantially circular when viewed in a direction vertical to the main surface 22b (Z-direction) of the second base portion 22. The curve of the depression 260 is preferably formed so as to correspond to the shape of a metal ball 70 that is used as the sealing member 7 to be described later.

The communication channel 261 is a cylindrical hole, for example. An end of the communication channel 261 is joined to the bottom surface of the depression 260, and the other end thereof is joined to the top surface of the pressure communication channel 25 (wall surface of the pressure communication channel 25 in the +Z direction).

When the diameter of the opening of the depression 260 is represented by ϕ1 and the diameter of the communication channel 261 is represented by ϕ2, ϕ1>ϕ2 is satisfied. Note that it is also possible to employ a structure in which the diameter ϕ2 of the communication channel 261 corresponds with a width w of the pressure communication channel 25.

In a region around the depression 260 on the main surface 22b of the second base portion 22, the metal layer 9 is formed. Specifically, as illustrated in FIG. 2A, the metal layer 9 is formed on the surface of the depression 260 and around the depression 260 on the main surface 22b of the second base portion 22. The metal layer 9 is formed of a metal material that is highly adhesive to the surface of the depression 260 and the sealing member 7.

On the metal layer 9, the sealing member 7 is formed. Specifically, the sealing member 7 is formed of a metal and is formed on the metal layer 9 so as to seal the depression 260. For example, the sealing member 7 is formed by melting a spherical metal material that is inserted to the depression 260 of the oil introduction passage 26 covered with the metal layer 9.

Note that the metal material for forming the sealing member 7 is desirably a material including gold. Thus, the sealing member 7 is unlikely to deform when a pressure is applied to the sealing member 7. Examples of the metal material include an alloy containing gold tin (AuSn) as a main component and an alloy containing gold germanium (AuGe) as a main component.

(2) Supporting Substrate 3

The supporting substrate 3 is a substrate for supporting the differential pressure sensor chip 2 on the diaphragm base 1 and for insulating the diaphragm base 1 and the differential pressure sensor chip 2 from each other. The supporting substrate 3 is a glass substrate, for example.

In the supporting substrate 3, through holes 30_1 and 30_2 formed through a main surface (seventh main surface) 3a and a main surface (eighth main surface) 3b opposite to the main surface 3a are formed. The through holes 30_1 and 30_2 are formed to be separated from each other in the plane direction on the main surface 3a and the main surface 3b.

The supporting substrate 3 is bonded to the differential pressure sensor chip 2. Specifically, when viewed in a direction vertical to the main surface 3a of the supporting substrate 3, the through hole 30_1 overlaps with the pressure introduction hole 21_1. In addition, the through hole 30_2 overlaps with the pressure introduction hole 21_2. In this state, the main surface 3b of the supporting substrate 3 is bonded to the main surface 20a of the first base portion 20.

Note that in a case where the first base portion 20 is silicon and the supporting substrate 3 is glass, for example, the main surface 20a of the first base portion 20 and the main surface 3b of the supporting substrate 3 are bonded by anodic bonding.

(3) Diaphragm Base 1

The diaphragm base 1 is a base that supports the differential pressure sensor chip 2 and that is formed of a metal material for guiding a pressure of a fluid that is a measurement target to the differential pressure sensor chip 2. Examples of the metal material include a stainless steel (SUS).

As illustrated in FIG. 1, the diaphragm base 1 includes a main surface (fifth main surface) 1a and a main surface (sixth main surface) 1b opposite to the main surface 1a.

In the diaphragm base 1, two through holes (first fluid pressure introduction hole and second fluid pressure introduction hole) 11_1 and 11_2 formed through the main surface 1a and the main surface 1b are formed. As illustrated in FIG. 1, in the through holes 11_1 and 11_2, an opening on the main surface 1a is formed to have a larger opening area than an opening on the main surface 1b.

The opening of the through hole 11_1 on the main surface 1a is covered with a diaphragm 10_1 for receiving a pressure from the fluid that is the measurement target. Similarly, the opening of the through hole 11_2 on the main surface 1a is covered with a diaphragm 10_2 for receiving a pressure from the fluid that is the measurement target. The diaphragms 10_1 and 10_2 are formed of a stainless steel (SUS), for example.

Hereinafter, the through holes 11_1 and 11_2 having openings covered with the diaphragms 10_1 and 10_2 will be referred to as “fluid pressure introduction holes 11_1 and 11_2”, respectively.

As illustrated in FIG. 1, on the main surface 1b of the diaphragm base 1, the differential pressure sensor chip 2 bonded to the supporting substrate 3 is placed and fixed. Specifically, the differential pressure sensor chip 2 bonded to the supporting substrate 3 is fixed onto the main surface 1b of the diaphragm base 1 by using a fixing member 5A in a state where, when viewed in the Z direction, the through holes 30_1 and 30_2 formed on the main surface 3a of the supporting substrate 3 overlap with the fluid pressure introduction holes 11_1 and 11_2.

Note that the fixing member 5A is a fluorine-based adhesive, for example.

In a region of the main surface 1b of the diaphragm base 1 other than a region to which the supporting substrate (the differential pressure sensor chip 2) is bonded, the relay substrate 4 is fixed. The relay substrate 4 is fixed onto the main surface 1b of the diaphragm base 1 by using a fixing member 6A formed of an epoxy-based adhesive, for example.

The relay substrate 4 is an external terminal for supplying power to the bridge circuit formed of the plurality of strain gauges 230_1 and 230_2 (piezoresistors) formed on the differential pressure sensor chip 2. In addition, the relay substrate 4 is a circuit substrate on which, for example, an external terminal for extracting an electric signal from the bridge circuit is formed.

Specifically, as illustrated in FIG. 1, the relay substrate 4 includes a plurality of electrode pads 40 as external output terminals formed on one of the main surfaces. The plurality of electrode pads 40 are connected to the electrode pads 29 formed on the main surface 20b of the differential pressure sensor chip 2, respectively, via bonding wires 8 formed of a metal material such as gold (Au), for example.

In addition, in the relay substrate 4, a plurality of external output pins (not illustrated) are provided in addition to the above electrode pads 40. Furthermore, a wiring pattern (not illustrated) that electrically connects each of the electrode pads 40 to a corresponding one of the external output pins is formed. Thus, the differential pressure sensor chip 2 is electrically connected to other circuits such as the signal processing circuit and a power supply circuit via the electrode pads 29, the bonding wires 8, the electrode pads 40, the wiring pattern, and the external output pins.

Note that the signal processing circuit, the power supply circuit, and the like may be provided on the relay substrate 4 or may be provided on another circuit substrate (not illustrated) that is connected to the relay substrate 4 via the external output pins.

The fluid pressure introduction holes 11_1 and 11_2 of the diaphragm base 1 and the pressure introduction holes 21_1 and 21_2 of the differential pressure sensor chip 2 communicate to each other through the through holes 30_1 and 30_2 of the supporting substrate 3.

The space inside the fluid pressure introduction holes 11_1 and 11_2 of the diaphragm base 1, the space inside the through holes 30_1 and 30_2 of the supporting substrate 3, and the space inside the pressure introduction holes 21_1 and 21_2 of the differential pressure sensor chip 2 are filled with a pressure transmission material 13. Similarly to the pressure transmission material 27, examples of the pressure transmission material 13 include silicone oil and fluorine oil. Hereinafter, the pressure transmission material 13 will also be referred to as “oil 13”.

During the manufacturing steps of the differential pressure transmitter 100, the oil 13 is introduced from oil introduction holes 14_1 and 14_2 that communicate to the fluid pressure introduction holes 11_1 and 11_2 formed in the diaphragm base 1. After the oil 13 has been introduced, the oil introduction holes 14_1 and 14_2 are sealed respectively with sealing members (e.g., spherical metal materials) 15_1 and 15_2 formed of a metal.

(4) Operations of Differential Pressure Transmitter

The differential pressure transmitter 100 having the above structure operates as follows.

For example, a case where the differential pressure transmitter 100 is mounted in a pipe line in which a fluid that is a measurement target flows will be considered. In this case, for example, the differential pressure transmitter 100 is mounted in the pipe line such that the pressure of the fluid on an upstream side (high-pressure side) of the pipe line is detected by the diaphragm 10_1 and the pressure of the fluid on a downstream side (low-pressure side) is detected by the diaphragm 10_2.

In this state, if the pressure of the fluid is applied to the diaphragm 10_1, displacement of the diaphragm 10_1 occurs. Along with the displacement, the oil 13 moves from the through hole 11_1 to the pressure introduction hole 21_1 of the differential pressure sensor chip 2. A pressure corresponding to this movement of the oil 13 is applied to the diaphragm 23_1 of the differential pressure sensor chip 2, and thereby displacement of the diaphragm 23_1 occurs.

Similarly, if the pressure of the fluid is applied to the diaphragm 10_2, displacement of the diaphragm 10_2 occurs. Along with the displacement, the oil 27 moves from the through hole 11_2 to the pressure introduction hole 21_2 of the differential pressure sensor chip 2. A pressure corresponding to this movement of the oil 27 is applied to the diaphragm 23_2 of the differential pressure sensor chip 2, and thereby displacement of the diaphragm 23_2 occurs.

At this time, the chambers 28_1 and 28_2 disposed to face the pressure introduction holes 21_1 and 21_2 with the diaphragms 23_1 and 23_2 interposed therebetween communicate to each other via the pressure communication channel 25 and are filled with the oil 27. Thus, the pressure corresponding to the movement of the oil 27 along with displacement of one of the diaphragms 23_1 and 23_2 is applied to the other of the diaphragms 23_1 and 23_2 through the pressure communication channel 25.

Accordingly, for example, in a case where the pressure applied from the pressure introduction hole 21_1 to the diaphragm 23_1 is larger than the pressure applied from the pressure introduction hole 21_2 to the diaphragm 23_2, displacement of the diaphragm 23_2 occurs by an amount corresponding to a differential between the two pressures in the −Z direction (toward the supporting substrate 3) in FIG. 1. On the other hand, displacement of the diaphragm 23_1 occurs by an amount corresponding to a differential between the two pressures in the +Z direction (toward the sealing member 7) in FIG. 1.

Displacement of the diaphragms 23_1 and 23_2 generates stress in the diaphragms 23_1 and 23_2, and the stress is applied to the strain gauges 230_1 and 230_2 formed in the diaphragms 23_1 and 23_2. Thus, an electric signal corresponding to the differential between the two pressures is output from the differential pressure sensor chip 2. This electric signal is input to a signal processing circuit that is not illustrated, and the signal processing circuit performs necessary signal processing, thereby obtaining information on the differential pressure of the fluid that is the measurement target. The information on the differential pressure is, for example, displayed on a display apparatus (not illustrated) of the differential pressure transmitter 100 or transmitted to an external device via a communication line.

(5) Method for Manufacturing Differential Pressure Sensor Chip 2

Next, a method for manufacturing the differential pressure sensor chip 2 will be described.

As an example herein, a chip fabrication process and an oil enclosing process will be separately described. In the chip fabrication process, a chip is fabricated by bonding the first base portion 20 and the second base portion 22 with the semiconductor film 23 interposed therebetween. In the oil enclosing process, the oil 27 as a pressure transmission material is enclosed in the semiconductor chip fabricated through the chip fabrication process.

(i) Chip Fabrication Process

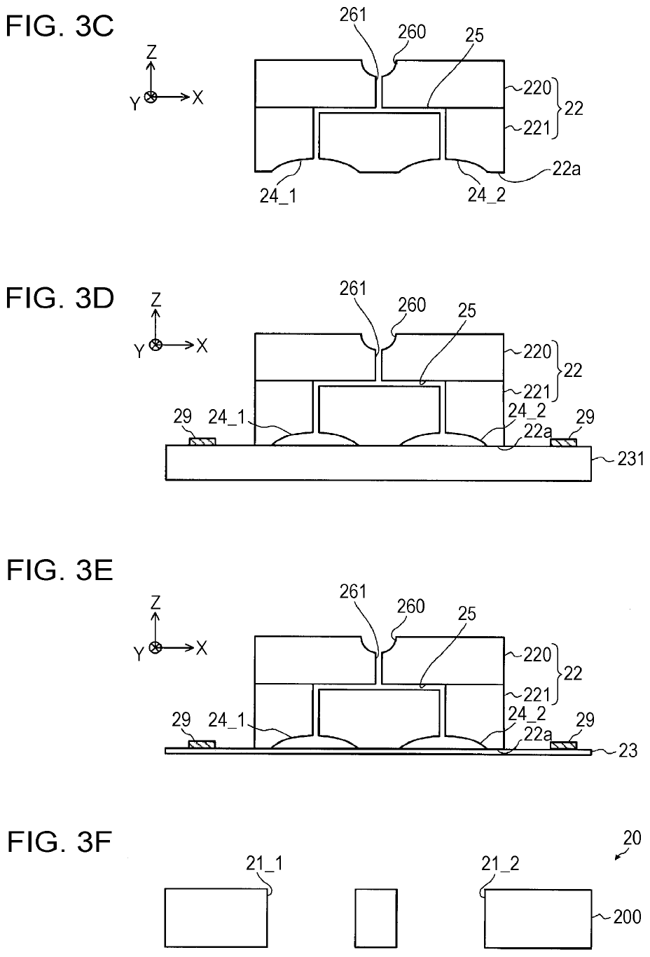

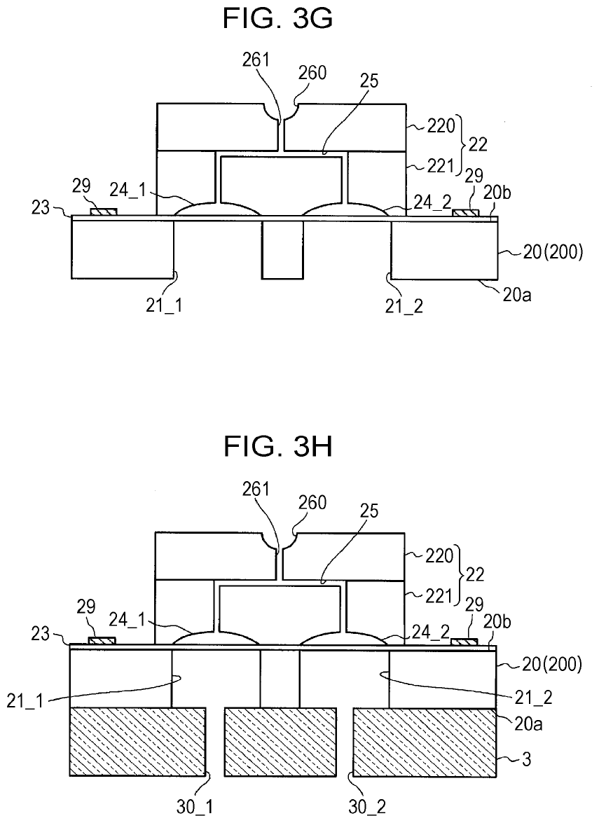

FIGS. 3A to 3H illustrate the chip fabrication process in the method for manufacturing the differential pressure sensor chip.

First, as illustrated in FIG. 3A, the oil introduction passage 26 is formed in a substrate 220 formed of silicon, for example (step S01). Specifically, by selectively removing the substrate 220 by a known semiconductor manufacturing technique, for example, a well-known photolithography technique and a dry etching technique, a through hole serving as the depression 260 and the communication channel 261, formed through two main facing surfaces of the substrate 220, is formed.

In addition, as illustrated in FIG. 3B, in a substrate 221 that is different from the substrate 220 and that is formed of silicon, for example, the stopper portions 24_1 and 24_2, the pressure communication channel 25, and the communication channel 261 of the oil introduction passage 26 are formed (step S02). Specifically, the substrate 221 is selectively removed by a known semiconductor manufacturing technique, for example, a well-known photolithography technique and a dry etching technique. Thus, a trench 250 is formed on one of two main facing surfaces of the substrate 221, and also the stopper portions 241 and 24_2 are formed on the other of the two main surfaces of the substrate 221. Furthermore, a through hole 250_1 formed through the trench 250 and the stopper portion 24_1 is formed, and also a through hole 2502 formed through the trench 250 and the stopper portion 24_2 is formed.

At this time, the stopper portions 24_1 and 24_2 each having a curve can be formed by selectively removing the substrate 221 by a well-known photolithography technique using a grayscale mask the light transmittance of which is changed and a dry etching technique (for example, see Japanese Unexamined Patent Application Publication No. 2005-69736).

Subsequently, as illustrated in FIG. 3C, the substrate 220 processed in step S01 and the substrate 221 processed in step S02 are bonded to each other (step S03). Specifically, by a known substrate bonding technique, in a state where the through hole as the communication channel 261 and the trench 250 are joined to each other, the substrate 220 and the substrate 221 are bonded to each other. Thus, the second base portion 22 in which the pressure communication channel 25 is formed by using one of the main surfaces of the substrate 220 and the trench 250 is fabricated.

Subsequently, as illustrated in FIG. 3D, a substrate 23_1 is bonded to the second base portion 22 (step S04). Note that the substrate 23_1 is a silicon substrate, for example. On a surface of the substrate 23_1, piezoresistors as the strain gauges 230_1 and 230_2, a wiring pattern (not illustrated) for electrical connection to the strain gauges 230_1 and 230_2 and the like, and the electrode pads 29 are formed.

Specifically, in step S04, by a known substrate bonding technique, the surface of the substrate 23_1 on which the strain gauges 230_1 and 230_2, the wiring pattern (not illustrated), and the electrode pads 29 are formed is bonded to the main surface 22a of the second base portion 22 on which the stopper portions 24_1 and 24_2 are formed.

Subsequently, as illustrated in FIG. 3E, a surface of the substrate 23_1 opposite to the surface bonded to the second base portion 22 is removed, thereby adjusting the thickness of the substrate 23_1 (step S05). Thus, the substrate 23_1 becomes the semiconductor film 23.

In addition, as illustrated in FIG. 3F, on a substrate 200 formed of silicon, for example, the pressure introduction holes 21_1 and 21_2 are formed (step S06). Specifically, the substrate 200 is selectively removed by a known semiconductor fabrication technique, for example, a well-known photolithography method and a dry etching method. Thus, two through holes as the pressure introduction holes 21_1 and 21_2 are formed through two main facing surfaces of the substrate 200.

Through the above process, the first base portion 20 is fabricated.

Subsequently, as illustrated in FIG. 3G, the second base portion 22, to which the semiconductor film 23 processed in step S05 is bonded, and the first base portion 20, fabricated in step S06, are bonded to each other (step S07). Specifically, by a known substrate bonding technique, in a state where the pressure introduction hole 21_1 and the stopper portion 24_1 are disposed to face each other and the pressure introduction hole 21_2 and the stopper portion 24_2 are disposed to face each other when viewed in a stacking direction (Z direction) of the second base portion 22, the semiconductor film 23 and the main surface 20b of the first base portion 20 (the substrate 200) are bonded to each other.

Subsequently, as illustrated in FIG. 3H, the chip fabricated in step S06 and the supporting substrate 3 formed of glass, for example, in which the through holes 30_1 and 30_2 are formed, are bonded to each other (step S08). Specifically, by a known anodic bonding technique, in a state where the through hole 30_1 and the pressure introduction hole 21_1 overlap with each other and the through hole 30_2 and the pressure introduction hole 21_2 overlap with each other when viewed in the stacking direction (Z direction) of the second base portion 22, the main surface 20a of the first base portion 20 is bonded to the supporting substrate 3.

Through the above process, the differential pressure sensor chip 2 to which the supporting substrate 3 is bonded and in which the oil is not enclosed is fabricated.

(ii) Oil Enclosing Process

Next, the oil enclosing process in the method for manufacturing the differential pressure sensor chip 2 will be described.

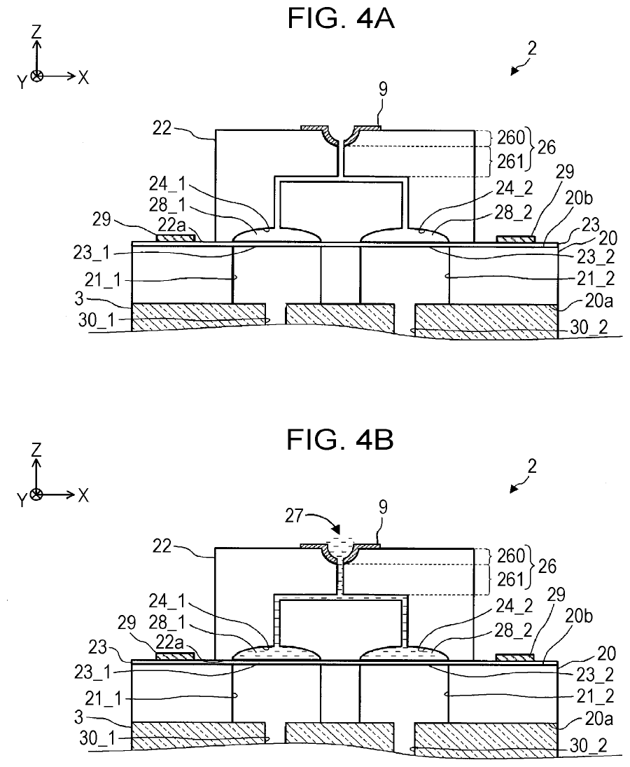

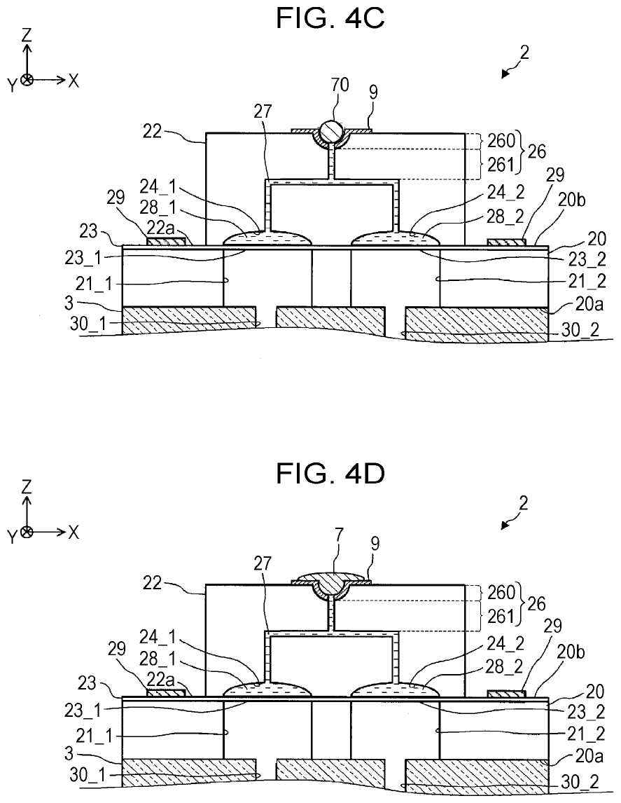

FIGS. 4A to 4D illustrate the oil enclosing process in the method for manufacturing the differential pressure sensor chip 2.

First, as illustrated in FIG. 4A, the metal layer 9 is formed on the surface of the depression 260 of the oil introduction passage 26 of the chip fabricated through the above chip fabrication process and the periphery of the depression 260 on the main surface 22b of the second base portion 22 (step S11). For example, by a well-known sputtering method, a vacuum evaporation method, or the like, a metal material is stacked to form the metal layer 9.

Subsequently, as illustrated in FIG. 4B, through the oil introduction passage 26 covered with the metal layer 9, the oil 27 as a pressure transmission material is introduced (step S12). For example, the differential pressure sensor chip 2 is disposed in a vacuum chamber, and the vacuum chamber is set in a high vacuum state. In this state, the oil 27 is introduced from the depression 260 of the oil introduction passage 26. In this manner, the oil introduction passage 26, the pressure communication channel 25, and the chambers 28_1 and 28_2 are filed with the oil 27.

Subsequently, as illustrated in FIG. 4C, the spherical metal member (metal ball) 70 formed of an alloy containing gold tin (AuSn) as a main component, for example, is disposed in the depression 260 of the oil introduction passage 26 (step S13).

Subsequently, as illustrated in FIG. 4D, the metal ball 70 is heated by laser irradiation, for example, to melt the metal ball 70 (step S14). Thus, the oil introduction passage 26 is sealed with the sealing member 7 obtained by melting the metal ball 70.

In the above manner, the differential pressure sensor chip 2 in which the oil 27 is sealed is fabricated.

As described above, the differential pressure sensor chip according to the present invention includes the chambers 28_1 and 28_2, which are respectively corresponding to the two diaphragms 23_1 and 23_2 disposed in parallel in a plane direction of the sensor chip, and the pressure communication channel 25 that makes the chamber 28_1 and the chamber 28_2 communicate to each other, and has the following structure. In a state where the oil introduction passage 26 that communicates to the pressure communication channel 25 is filled with the oil, the depression 260 that is an opening of the oil introduction passage 26 and that is covered with the metal layer 9 is sealed with the sealing member 7 formed of a metal.

This makes it possible to reduce the amount of oil introduced to the differential pressure sensor chip compared with a method of the related art for sealing the oil in the differential pressure sensor chip by using the oil filling pipe. For example, a case will be considered in which, after the oil 27 has been introduced from the depression 260 of the oil introduction passage 26, the metal ball 70 disposed within the depression 260 covered with the metal layer 9 is melted to seal the oil introduction passage 26. In such a case, compared with a case where sealing is performed by using the oil filling pipe of the related art, the amount of oil accumulated in a space other than the two chambers 28_1 and 28_2 and the pressure communication channel 25 can be reliably reduced.

Accordingly, by using the differential pressure sensor chip according to the present invention, a necessary and sufficient amount of the pressure transmission material can be enclosed in the sensor chip. Accordingly, it is possible to realize a differential pressure transmitter in which the pressure detection sensitivity may not be decreased owing to a change in an ambient environment, or the diaphragms may not be broken.

In addition, by using the differential pressure sensor chip according to the present invention, since no oil filling pipe is used and no adhesive is used for fixing the oil filling pipe to the sensor chip, the amount of oil can be easily controlled.

Furthermore, by using the differential pressure sensor chip according to the present invention, no component whose front end protrudes from the chip is used, such as the oil filling pipe that may become a physical obstacle in a wafer process, a packaging process, and the like. Accordingly, compared with a method of the related art for manufacturing the differential pressure transmitter, the degree of freedom of the manufacturing steps is increased, and the manufacturing cost of the differential pressure transmitter can be reduced.

From the above, by using the differential pressure sensor chip according to the present invention, it is possible to realize, at a lower cost, a differential pressure transmitter including a parallel-diaphragm-type differential pressure sensor chip in which a necessary and sufficient amount of a pressure transmission material is enclosed.

In addition, in the differential pressure sensor chip according to the present invention, since the depression 260 of the oil introduction passage 26 is formed as a hemispherical hole, in a case where the metal ball 70 is used as the sealing member 7, it is possible to increase the adhesion between the metal ball 70 and the depression 260. This can increase the sealing performance for the oil 27 and also can suppress generation of a space where the metal ball 70 and the depression 260 are not bonded, in which the oil 27 may be accumulated.

### Expansion of Embodiment

Although the invention made by the present inventors has been specifically described above based on the embodiment, the present invention is not limited to this, and it is needless to say that various modifications can be made without departing from the spirit thereof.

For example, although the above embodiment has illustrated a case where the depression 260, which is an opening of the oil introduction passage 26, is formed as a hemispherical hole, the shape of the depression 260 is not limited to this. Specific examples will be described below.

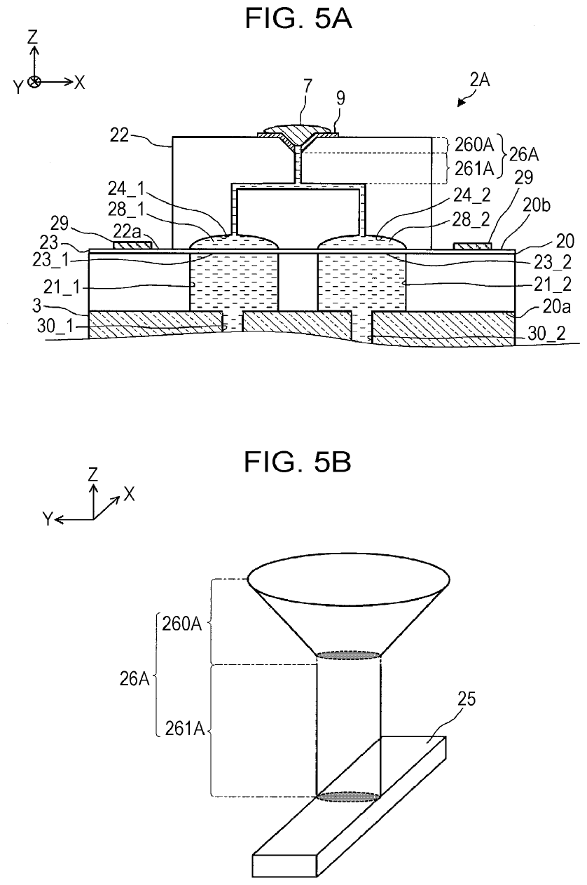

FIG. 5A is a sectional view illustrating a schematic structure of a first example of the oil introduction passage. FIG. 5B is a perspective view illustrating the schematic structure of the first example of the oil introduction passage.

As in a differential pressure sensor chip 2A illustrated in FIGS. 5A and 5B, a depression 260A of an oil introduction passage 26A may be in the form of an earthenware mortar (cone). Specifically, the depression 260A of the oil introduction passage 26A may be formed so as to have a smaller diameter continuously toward a communication channel 261A.

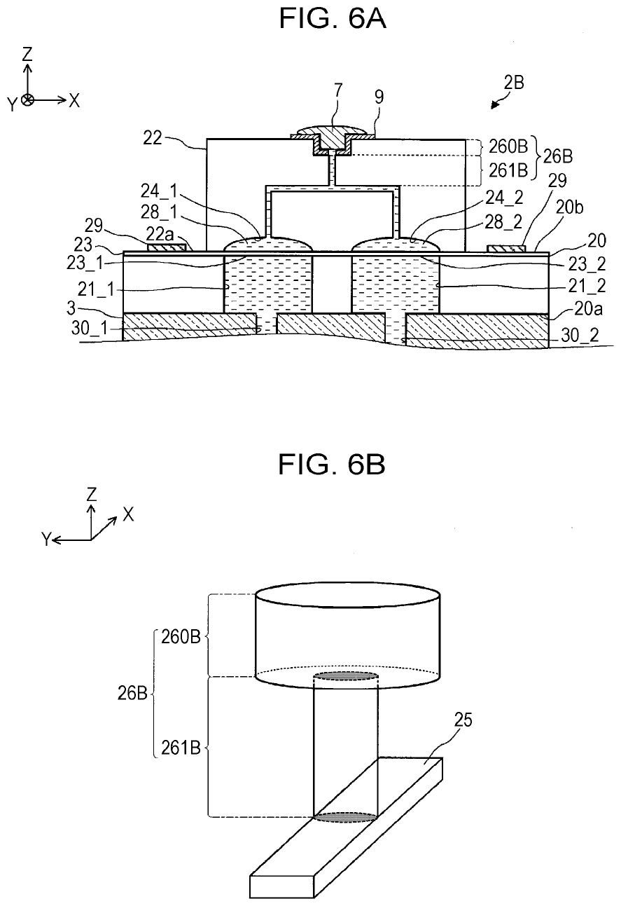

FIG. 6A is a sectional view illustrating a schematic structure of a second example of the oil introduction passage. FIG. 6B is a perspective view illustrating the schematic structure of the second example of the oil introduction passage.

As in a differential pressure sensor chip 2B illustrated in FIGS. 6A and 6B, a depression 260B of an oil introduction passage 26B may be formed as a cylinder extending in the longitudinal direction of a communication channel 261B as the axial direction.

Note that as illustrated in FIGS. 5A, 5B, 6A, and 6B, the metal layer 9 is formed so as to correspond to the shape of the hole of the depressions 260A and 260B.

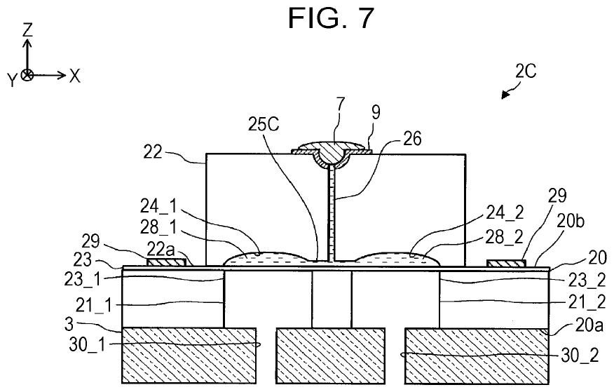

In addition, the shape of the pressure communication channel formed in the differential pressure sensor chip is not limited to the one illustrated in the above embodiment. For example, as in a differential pressure sensor chip 2C illustrated in FIG. 7, a pressure communication channel 25C may be used. The pressure communication channel 25C has a shape to join the chamber 28_1 and the chamber 28_2 along the main surface 22b of the second base portion 22.

It is needless to say that the differential pressure sensor chip 2 according to the above embodiment is applicable not only to the differential pressure transmitter 100 having the structure illustrated in FIG. 1 and the like, but also to a differential pressure transmitter having any structure. That is, the differential pressure transmitter 100 illustrated in the above embodiment is merely an example, and the differential pressure sensor chip according to the present invention is also applicable to a differential pressure transmitter in which a material, a shape, and the like of the diaphragm base 1 are different from those in the differential pressure transmitter 100, depending on a specification, usage, and the like required as the differential pressure transmitter.

### REFERENCE SIGNS LIST

100 differential pressure transmitter

1 diaphragm base

1a, 1b main surface

2, 2A to 2C differential pressure sensor chip

3 supporting substrate

3a, 3b main surface

4 relay substrate

5A, 6A fixing member

7 sealing member

70 metal ball

8 bonding wire

9 metal layer

10_1, 10_2 diaphragm

11_1, 11_2 fluid pressure introduction hole

13 oil

14_1, 14_2 oil introduction hole

15_1, 15_2 sealing member

20 first base portion

20a, 20b main surface of first base portion 20

21_1, 21_2 pressure introduction hole

22 second base portion

22a, 22b main surface of second base portion 22

23 semiconductor film

23_1, 23_2 diaphragm

24_1, 24_2 stopper portion

25, 25C pressure communication channel

26, 26A, 26B oil introduction passage

27 oil

28_1, 28_2 chamber

29, 40 electrode pad

30_1, 30_2 through hole

230_1, 230_2 strain gauge

260, 260A, 260B depression

261, 261A, 261B communication channel

1. A differential pressure sensor chip comprising:
a first base portion including a first main surface, a second main surface opposite to the first main surface, and a first pressure introduction hole and a second pressure introduction hole that are each open on the first main surface and the second main surface;
a semiconductor film formed on the second main surface of the first base portion; and
a second base portion including a third main surface and a fourth main surface opposite to the third main surface, the third main surface being bonded to the semiconductor film,
wherein the semiconductor film includes
a first diaphragm configured to cover an end of the first pressure introduction hole,
a second diaphragm configured to cover an end of the second pressure introduction hole,
a first strain gauge provided for the first diaphragm and configured to detect a pressure of a fluid that is a measurement target, and
a second strain gauge provided for the second diaphragm and configured to detect a pressure of the fluid that is the measurement target, and
wherein the second base portion includes
a first depression formed at a position on the third surface facing the first pressure introduction hole with the first diaphragm interposed therebetween and forming a first chamber together with the first diaphragm,
a second depression formed at a position on the third surface facing the second pressure introduction hole with the second diaphragm interposed therebetween and forming a second chamber together with the second diaphragm,
a first communication channel that makes the first chamber and the second chamber communicate to each other,
a pressure-transmission-material introduction passage including a third depression formed on the fourth main surface and a second communication channel that makes the third depression and the first communication channel communicate to each other,
a metal layer formed on a surface of the third depression,
a pressure transmission material that fills the first chamber, the second chamber, the first communication channel, and the pressure-transmission-material introduction passage, and
a sealing member that seals the third depression on the metal layer and that is formed of a metal.

2. The differential pressure sensor chip according to claim 1,
wherein the third depression is a hemispherical hole formed on the fourth main surface.

3. The differential pressure sensor chip according to claim 1,
wherein the sealing member is formed of a metal material that is melted within the third depression.

4. The differential pressure sensor chip according to claim 3,
wherein the metal material includes gold.

5. A differential pressure transmitter comprising:
the differential pressure sensor chip according to claim 1;
a base including a fifth main surface, a sixth main surface opposite to the fifth main surface, and a first fluid pressure introduction hole and a second fluid pressure introduction hole that are each open on the fifth main surface and the sixth main surface;
a third diaphragm formed on the fifth main surface of the base to cover an end of the first fluid pressure introduction hole;
a fourth diaphragm formed on the fifth main surface of the base to cover an end of the second fluid pressure introduction hole; and
a supporting substrate including a seventh main surface, an eighth main surface opposite to the seventh main surface, and a first through hole and a second through hole that are each open on the seventh main surface and the eighth main surface, the seventh main surface being fixed onto the base, the eighth main surface being bonded to the first main surface of the first base portion, the supporting substrate supporting the differential pressure sensor chip,
wherein the first fluid pressure introduction hole and the first through hole communicate to each other, and
wherein the second fluid pressure introduction hole and the second through hole communicate to each other.

6. A method for manufacturing a differential pressure sensor chip that detects a differential pressure of a fluid that is a measurement target, the method comprising:
a first step of forming a semiconductor chip, the semiconductor chip including
a first diaphragm and a second diaphragm,
a first strain gauge provided for the first diaphragm and configured to detect a pressure of the fluid that is the measurement target,
a second strain gauge provided for the second diaphragm and configured to detect a pressure of the fluid that is the measurement target,
a first pressure introduction hole configured to introduce a pressure to the first diaphragm,
a second pressure introduction hole configured to introduce a pressure to the second diaphragm,
a first stopper portion provided to face the first pressure introduction hole with the first diaphragm interposed therebetween and formed to be separated from the first diaphragm,
a second stopper portion provided to face the second pressure introduction hole with the second diaphragm interposed therebetween and formed to be separated from the second diaphragm,
a first chamber between the first diaphragm and the first stopper portion,
a second chamber between the second diaphragm and the second stopper portion,
a first communication channel that makes the first chamber and the second chamber communicate to each other, and
a pressure-transmission-material introduction passage including one end for introducing a pressure transmission material and another end joined to the first communication channel,
a second step of forming the metal layer on a wall surface on the one end of the pressure-transmission-material introduction passage;
a third step of introducing the pressure transmission material from the one end of the pressure-transmission-material introduction passage after the first step; and
a fourth step of providing a metal material in contact with the metal layer on the one end of the pressure-transmission-material introduction passage and for sealing the one end of the pressure-transmission-material introduction passage by melting the metal material after the third step.

7. The method for manufacturing the differential pressure sensor chip according to claim 6,
wherein the semiconductor chip includes
a first base portion including a first main surface, a second main surface opposite to the first main surface, and the first pressure introduction hole and the second pressure introduction hole that are each open on the first main surface and the second main surface,
a semiconductor film that is formed on the second main surface of the first base portion to cover the first pressure introduction hole and the second pressure introduction hole, in which, when viewed in a direction vertical to the second main surface, a region overlapping with the first pressure introduction hole serves as the first diaphragm and a region overlapping with the second pressure introduction hole serves as the second diaphragm, and
a second base portion including a third main surface, a fourth main surface opposite to the third main surface, and the first stopper portion and the second stopper portion formed on the third main surface, the first communication channel that makes the first stopper portion and the second stopper portion communicate to each other, a depression formed on the fourth main surface, and the pressure-transmission-material introduction passage formed of a second communication channel that makes the depression and the first communication channel communicate to each other, in which, when viewed in a direction vertical to the third main surface, in a state where at least a part of the first stopper portion overlaps with the first diaphragm and at least a part of the second stopper portion overlaps with the second diaphragm, the third main surface is formed on the semiconductor film on the second main surface of the first base portion.

8. The method for manufacturing the differential pressure sensor chip according to claim 7,
wherein the depression is a hemispherical hole formed on the fourth main surface.
